(19) United States
(12) Patent Application Publication
(10) Pub. No.: US 2026/0314203 A1
(43) Pub. Date: Oct. 8, 2026

(54) DISPLAY PANEL AND DISPLAY APPARATUS

(71) Applicant: Wuhan Tianma Microelectronics Co., Ltd., Wuhan (CN)

(72) Inventors: Wei CHENG, Wuhan (CN); Lei LI, Wuhan (CN)

(73) Assignee: Wuhan Tianma Microelectronics Co., Ltd., Wuhan (CN)

(21) Appl. No.: 19/686,262

(22) Filed: May 22, 2026

(30) Foreign Application Priority Data
Nov. 4, 2025 (CN) 202511605637.8

(51) Int. Cl. H10K 59/131; H10K 59/40

(52) U.S. Cl. CPC H10K 59/131; H10K 59/40

(57) ABSTRACT

Provided is a display panel, which includes a substrate, a first signal trace, a first insulating layer, a second insulating layer, and an isolation protection portion. In the first region, the second insulating layer directly contacts the first signal trace, and in the second region, the first insulating layer is located between the second insulating layer and the first signal trace. In the second region, the isolation protection portion overlaps with the first signal trace and is located on a side of the first insulating layer away from the substrate. A first voltage signal received by the first signal trace and a second voltage signal received by the isolation protection portion have opposite voltage types.

### CROSS-REFERENCE TO RELATED APPLICATION

The present application claims priority to Chinese Patent Application No. 202511605637.8, filed on Nov. 4, 2025, the content of which is incorporated herein by reference in its entirety.

### TECHNICAL FIELD

The present disclosure relates to the field of display technologies and, in particular, to a display panel and a display apparatus.

### BACKGROUND

With the continuous development of science and technology, more and more display products, such as mobile phones, tablets, laptops, and smart wearable devices, are widely used in people’s daily lives and work, bringing great convenience and becoming indispensable and important tools in modern life.

Currently, the demand for narrow bezels in the OLED (Organic Light-Emitting Diode) product market is growing day by day. As bezels continue to narrow, a series of disadvantages have become prominent. For example, moisture intrusion in the bezel region leads to reduced product reliability and problems such as display abnormalities.

Therefore, how to reduce or avoid moisture intrusion into display products to improve the reliability of display products has become one of the technical problems that urgently needs to be solved at this stage.

In order to solve the above technical problems, the present disclosure provides a display panel and a display apparatus, intended to reduce or avoid moisture intrusion and improve product reliability.

In a first aspect, an embodiment of the present disclosure provides a display panel, having a display region and a non-display region at least partially surrounding the display region. The display panel includes a substrate and a signal trace located on a side of the substrate, a first insulating layer, a second insulating layer, and an isolation protection portion. The non-display region includes a step region, the step region is located on a side of the display region in a first direction, and includes a first region and a second region that are arranged in the first direction, and the first region is located between the second region and the display region. The signal trace includes a first signal trace, and the first signal trace extends at least from the first region to the second region. The first insulating layer is located on a side of the first signal trace away from the substrate. The second insulating layer is located on a side of the first insulating layer away from the substrate. In the first region, the second insulating layer directly contacts the first signal trace, and in the second region, the first insulating layer is located between the second insulating layer and the first signal trace. The isolation protection portion is located at least in the second region. In a direction perpendicular to a plane of the substrate, the isolation protection portion overlaps with the first signal trace, and the isolation protection portion is located on the side of the first insulating layer away from the substrate. The first signal trace is configured to receive a first voltage signal, the isolation protection portion is configured to receive a second voltage signal, and the first voltage signal and the second voltage signal have opposite voltage types.

In a second aspect, based on the same inventive concept, an embodiment of the present disclosure provides a display apparatus, including a display panel having a display region and a non-display region at least partially surrounding the display region. The display panel includes a substrate and a signal trace located on a side of the substrate, a first insulating layer, a second insulating layer, and an isolation protection portion. The non-display region includes a step region, the step region is located on a side of the display region in a first direction, and includes a first region and a second region that are arranged in the first direction, and the first region is located between the second region and the display region. The signal trace includes a first signal trace, and the first signal trace extends at least from the first region to the second region. The first insulating layer is located on a side of the first signal trace away from the substrate. The second insulating layer is located on a side of the first insulating layer away from the substrate. In the first region, the second insulating layer directly contacts the first signal trace, and in the second region, the first insulating layer is located between the second insulating layer and the first signal trace. The isolation protection portion is located at least in the second region. In a direction perpendicular to a plane of the substrate, the isolation protection portion overlaps with the first signal trace, and the isolation protection portion is located on the side of the first insulating layer away from the substrate. The first signal trace is configured to receive a first voltage signal, the isolation protection portion is configured to receive a second voltage signal, and the first voltage signal and the second voltage signal have opposite voltage types..

### BRIEF DESCRIPTION OF DRAWINGS

The drawings herein are incorporated into and constitute a part of the specification, illustrate embodiments of the present disclosure, and with the specification, serve to explain the principles of the present disclosure.

To clearly illustrate the technical solutions of the embodiments of the present disclosure or the related art, the drawings required in the embodiments or the related art are briefly introduced below. It is appreciated that for those skilled in the art, other drawings can be obtained according to these drawings without any creative effort.

FIG. 1 is a schematic plan view of a display panel according to an embodiment of the present disclosure;

FIG. 2 is a film layer schematic diagram of a display region of the display panel in FIG. 1;

FIG. 3 is a cross-sectional view along a line CC of a display panel in FIG. 1;

FIG. 4 is another cross-sectional view along a line CC of a display panel in FIG. 1;

FIG. 5 is a schematic circuit diagram of a pixel driving circuit according to an embodiment of the present disclosure;

FIG. 6 is a diagram showing a relative positional relationship among an isolation protection portion, a first signal trace, and a second signal trace in a step region;

FIG. 7 is a cross-sectional view along a line DD of a display panel in FIG. 6;

FIG. 8 is another cross-sectional view along a line DD of a display panel in FIG. 6;

FIG. 9 is a schematic plan view of another display panel according to an embodiment of the present disclosure;

FIG. 10 is a schematic plan view of a touch electrode according to an embodiment of the present disclosure;

FIG. 11 is a diagram showing another relative positional relationship among an isolation protection portion, a first signal trace, and a second signal trace in a step region;

FIG. 12 is a cross-sectional view along a line EE of a display panel in FIG. 11;

FIG. 13 is another cross-sectional view along a line EE of a display panel in FIG. 11;

FIG. 14 is another cross-sectional view along a line CC of a display panel in FIG. 1;

FIG. 15 is another cross-sectional view along a line EE of a display panel in FIG. 11;

FIG. 16 is another cross-sectional view along a line EE of a display panel in FIG. 11;

FIG. 17 is a schematic plan view of another display panel according to an embodiment of the present disclosure;

FIG. 18 is a schematic plan view of another display panel according to an embodiment of the present disclosure;

FIG. 19 is a schematic plan view of a first region in a display panel according to the embodiments of FIG. 17 and FIG. 18;

FIG. 20 is a cross-sectional view along a line FF of a display panel in FIG. 19;

FIG. 21 is another cross-sectional view along a line FF of a display panel in FIG. 19;

FIG. 22 is a cross-sectional view along a line GG of a display panel in FIG. 18; and

FIG. 23 is a schematic structural diagram of a display apparatus according to an embodiment of the present disclosure.

### DESCRIPTION OF EMBODIMENTS

To clearly understand the objectives, features, and advantages of the present disclosure, the technical solutions of the present disclosure will be further described below. It should be noted that the embodiments of the present disclosure and the features in the embodiments can be combined with each other.

In the following description, many specific details are set forth in order to provide a full understanding of the present disclosure, but the present disclosure can also be implemented in other ways different from those described herein. It is appreciated that the embodiments in the specification are merely a part, rather than all, of the embodiments of the present disclosure.

Current display products, such as OLED products, pursue extreme narrow bezels, and the path for moisture intrusion into the display region has also become shorter, which brings significant reliability challenges. A bezel region of an OLED product is usually provided with metal traces, such as power supply lines, for providing power signals to pixels in the display region. When an OLED display product is provided with a polarizer, in a step region of the display product, a positive electrical signal in the power supply line will attract negatively charged iodine ions in the polarizer, causing the iodine ions to gather near the power supply line. When moisture intrudes into the bezel region, under a high-temperature environment, ammonia in some internal film layers of the display product, such as an encapsulation layer, dissolves in water and accelerates an ionization reaction of water. The negatively charged iodine ions in the polarizer further react with ions generated by the water ionization reaction under high temperature, and the generated oxides will cause corrosion to the power supply line made of metal material, resulting in abnormal dark spots in a region at the boundary between the display region and the step region, which seriously affects the display effect.

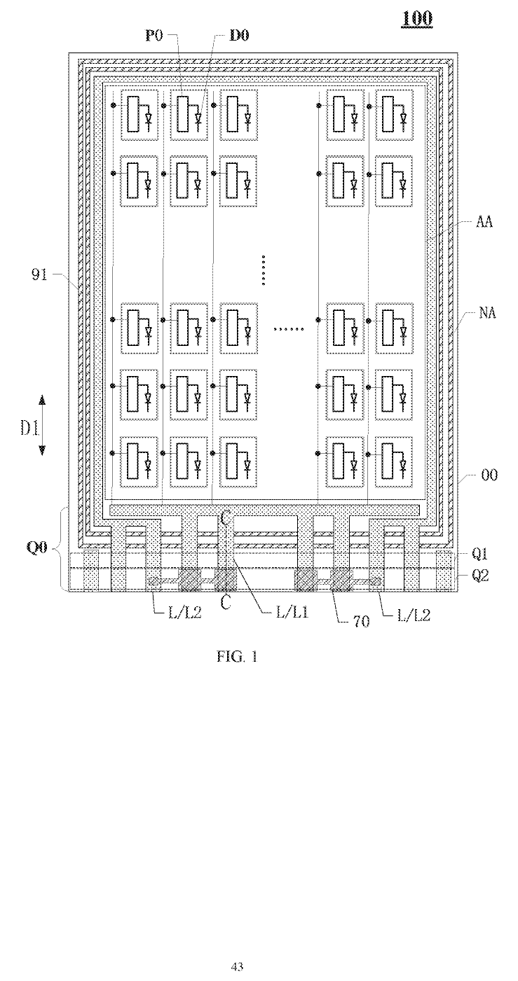

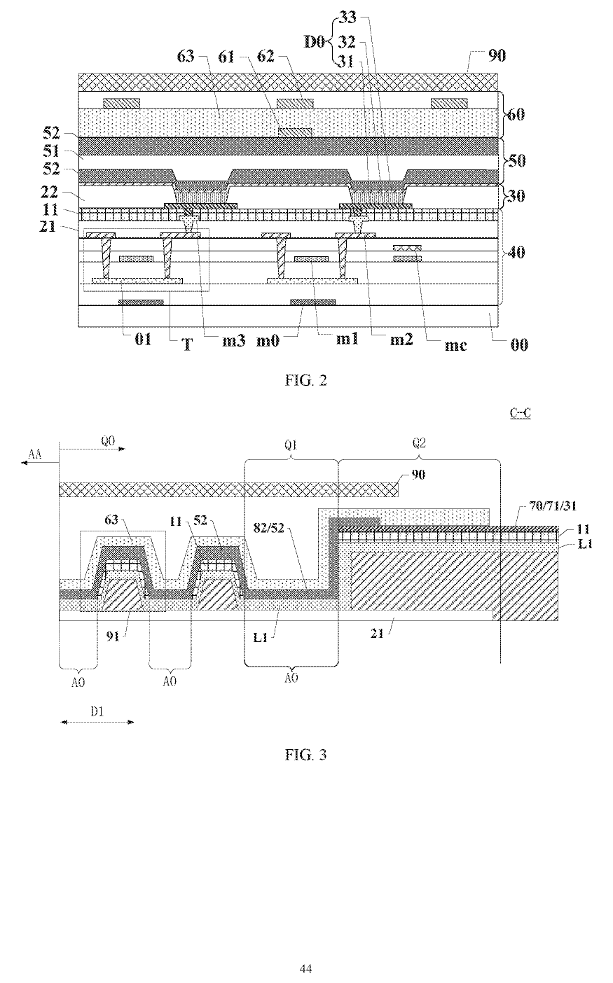

To solve the above problems, an embodiment of the present disclosure provides a display panel. FIG. 1 is a schematic plan view of a display panel according to an embodiment of the present disclosure, FIG. 2 is a film layer schematic diagram of a display region of the display panel in FIG. 1, and FIG. 3 is a cross-sectional view along a line CC of the display panel in FIG. 1. It should be noted that FIG. 1 only takes a display panel with a rectangular structure as an example for illustration and does not limit the actual shape of the display panel. In some embodiments of the present disclosure, the display panel may also be embodied in any other feasible shapes such as a circle or a rounded rectangle. In some embodiments, the display panel according to the embodiments may be an organic light-emitting display panel, and the corresponding light-emitting element is an organic light-emitting element. In some other embodiments of the present disclosure, the display panel may also employ a display panel of an inorganic light-emitting diode display technology, such as a Micro LED display panel, a Mini LED display panel, etc., which is not limited by the present disclosure.

The present disclosure takes an OLED display panel as an example for illustration. Referring to FIG. 2, the basic structure of the light-emitting element D0 includes a first electrode 31, a light-emitting layer 32, and a second electrode 33. The first electrode 31 is an anode, and the second electrode 33 is a cathode. When a power supply provides an appropriate voltage, holes generated by the first electrode 31 and electrons generated by the second electrode 33 combine in the light-emitting layer 32 to produce bright light. In some embodiments, the display panel includes a substrate 00, an array layer 40, and a light-emitting functional layer 30. The light-emitting functional layer 30 includes a pixel definition layer 22 defining a plurality of pixel openings. The light-emitting layer 32 is located at least in the pixel openings. In a direction perpendicular to the substrate 00, the first electrode 31 and the second electrode 33 are located on two sides of the light-emitting layer 32, respectively, and the first electrode 31 is located on a side of the second electrode 33 facing the substrate 00. In some embodiments, an encapsulation layer 50 is further disposed on a side of the second electrode 33 away from the first electrode 31, and a polarizer 90 is disposed on a side of the encapsulation layer 50 away from the substrate 00. In some embodiments, the encapsulation layer 50 includes an organic layer 51 and two inorganic layers 52 arranged in a stacked manner, and the organic layer 51 is located between the two inorganic layers 52. A pixel driving circuit is disposed in the array layer 40 for providing a driving voltage to the light-emitting element D0 to drive it to emit light, and the pixel driving circuit includes a plurality of transistors T. In some embodiments, in the array layer 40, a gate electrode of the transistor T is disposed in a first metal layer m1, and a source electrode and a drain electrode of the transistor are disposed in a second metal layer m2. In some embodiments, the array layer 40 further includes an active layer 01 disposed on a side of the first metal layer m1 facing the substrate 00 and an auxiliary metal layer m0 disposed on a side of the active layer 01 facing the substrate 00. In a direction perpendicular to a plane of the substrate, both the first metal layer m1 and the auxiliary metal layer m0 overlap with the active layer 01, and the auxiliary metal layer m0 serves to block light to avoid light from affecting the active layer 01. In some embodiments, a capacitor metal layer mc is further disposed between the first metal layer m1 and the second metal layer m2, and the capacitor metal layer mc can form a capacitor structure with the second metal layer m2 or the first metal layer m1. In some embodiments, a third metal layer m3 is further disposed on a side of the second metal layer m2 away from the substrate 00. An additional metal layer may be disposed on a side of the third metal layer m3 away from the substrate according to actual needs, which is not limited by the present disclosure. Signal lines can be arranged in each metal layer. For example, a power supply line may be arranged in the third metal layer m3.

Referring to FIG. 1 to FIG. 3, the display panel 100 according to an embodiment of the present disclosure has a display region AA and a non-display region NA at least partially surrounding the display region AA. The non-display region NA includes a step region Q0, the step region Q0 is located on a side of the display region AA in a first direction D1, the step region Q0 includes a first region Q1 and a second region Q2 arranged in the first direction D1, and the first region Q1 is located between the second region Q2 and the display region AA. That is, in the step region Q0, the first region Q1 is closer to the display region AA than the second region Q2.

The display panel 100 includes a substrate 00 and a signal trace L located on a side of the substrate 00, a first insulating layer 11, a second insulating layer 82, and an isolation protection portion 70.

The signal trace L includes a first signal trace L1, and the first signal trace L1 extends at least from the first region Q1 to the second region Q2. In some embodiments, the first signal trace L1 is located in the third metal layer m3. In some embodiments of the present disclosure, the first signal trace L1 may also be located in the second metal layer m2, or may be formed as a dual-layer wiring structure in the second metal layer m2 and the third metal layer m3 to reduce voltage drop.

The first insulating layer 11 is located on a side of the first signal trace L1 away from the substrate.

The second insulating layer 82 is located on a side of the first insulating layer 11 away from the substrate. In the first region Q1, the second insulating layer 82 is in direct contact with the first signal trace L1, and in the second region Q2, the first insulating layer 11 is located between the second insulating layer 82 and the first signal trace L1.

The isolation protection portion 70 is located at least in the second region Q2. In the direction perpendicular to the plane of the substrate, the isolation protection portion 70 overlaps with the first signal trace L1, and is located on a side of the first insulating layer 11 away from the substrate. The first signal trace L1 receives a first voltage signal, the isolation protection portion 70 receives a second voltage signal, and the first voltage signal and the second voltage signal have opposite voltage types.

In the related art, in the step region Q0, a positive electrical signal in the first signal trace L1 may attract negatively charged iodine ions in the polarizer 90, causing the iodine ions to gather near the first signal trace L1. When moisture intrudes into the bezel region, under a high-temperature environment, ammonia in some internal film layers of the display product, such as an inorganic insulating layer, dissolves in water and accelerates the ionization reaction of water. The negatively charged iodine ions in the polarizer 90 further react with ions generated by the water ionization reaction under high temperature, and the generated oxides will cause corrosion to the first signal trace L1 made of metal material, resulting in abnormal dark spots in a region at the boundary between the display region AA and the bezel region, which seriously affects the display effect. Therefore, in some embodiments of the present disclosure, the isolation protection portion 70 is introduced into the second region Q2 of the step region Q0. When the isolation protection portion 70 is located on the side of the first insulating layer 11 away from the substrate, since the first signal trace L1 is located on the side of the first insulating layer 11 facing the substrate, it is equivalent to introducing the isolation protection portion 70 on the side of the first signal trace L1 facing a light-emitting surface of the display panel. When the display panel includes the polarizer 90, it is equivalent to introducing the isolation protection portion 70 between the first signal trace L1 and the polarizer 90.

In the embodiments, the first voltage signal and the second voltage signal have opposite voltage types. That is, when the first voltage signal received by the first signal trace L1 is a positive potential signal, the second voltage signal received by the isolation protection portion 70 is a negative potential signal. When the first voltage signal received by the first signal trace L1 is a negative potential signal, the second voltage signal received by the isolation protection portion 70 is a positive potential signal. In this way, opposite electric fields are formed between the isolation protection portion 70 and the first signal trace L1. Taking an example where the first voltage signal received by the first signal trace L1 is a positive potential signal and the second voltage signal received by the isolation protection portion 70 is a negative potential signal, a negative electric field will be formed around the isolation protection portion 70. When negatively charged iodine ions are precipitated from the polarizer 90, the negative electric field around the isolation protection portion 70 will exert a strong electrostatic repulsion force on the negatively charged iodine ions. Through this electrostatic repulsion, iodine ions can be effectively prevented from, or significantly reduced in, gathering near the first signal trace L1 with positive potential, thereby fundamentally eliminating or mitigating the risk of corrosion caused by iodine ions to the first signal trace L1. Once the iodine ions are effectively repelled, the probability of them reacting with moisture ionization products to generate oxides that corrode power supply lines will be greatly reduced. In this way, chemical corrosion of the first signal trace L1 made of metal material is directly reduced or eliminated, thereby solving the problem of abnormal dark spots caused by the corrosion of the first signal trace L1 at the boundary between the display region and the step region, ensuring the uniformity and aesthetics of the display image, and thus helping to improve the long-term reliability of the display panel under harsh environments such as high temperature and high humidity.

Furthermore, in the present disclosure, in the direction perpendicular to the substrate, the isolation protection portion 70 overlaps with the first signal trace L1 and is located on the side of the first insulating layer 11 away from the substrate. The isolation protection portion 70 can spatially shield the first signal trace L1 from direct contact with moisture, or at least provide an extra obstruction, thereby helping to improve the waterproof performance of the second region Q2. Meanwhile, since the isolation protection portion 70 can inhibit the accumulation of iodine ions, it also indirectly blocks iodine ion corrosion, i.e., the contact between iodine ions and the first signal trace L1, thereby effectively improving the reliability of the display panel.

In some embodiments, the first insulating layer 11 is an organic material layer, and the second insulating layer 82 is an inorganic material layer. An organic material layer has better flexibility than an inorganic material layer, and an inorganic material layer has better waterproof performance than an organic material layer. In the first region Q1, the second insulating layer 82 is in direct contact with the first signal trace L1, which means that the first insulating layer 11 is not provided in the first region Q1. This is equivalent to using the first region Q1 to block the transmission path of organic layers between the second region Q2 and the display region AA, thereby cutting off the path of moisture transmission from organic layers to the first region Q1 and the display region AA. In the first region Q1, the second insulating layer 82 is used for waterproof protection of the first signal trace L1, avoiding the introduction of organic layers with relatively poor waterproof performance, which can effectively utilize the waterproof characteristics of the second insulating layer 82 and improve the waterproof performance of the first region Q1. When the display panel has a narrow bezel or an extremely narrow bezel structure, since the moisture intrusion path is extremely short, the first region Q1 near the display region AA is the region most susceptible to moisture intrusion affecting the display effect. Therefore, using the second insulating layer 82 (inorganic material layer) with better waterproof performance as the main insulating layer while removing the organic material layer in the first region Q1 can significantly improve the reliability of this region.

To achieve the design of a narrow bezel or an extremely narrow bezel, the film layer on the side of the second region Q2 away from the display region AA may be bent to a non-light-emitting surface of the display panel. Therefore, when the first insulating layer 11 (organic material layer) is retained in the second region Q2, the first insulating layer 11 can provide the necessary buffering and stress release for bending, avoiding cracks in the rigid inorganic layer during bending, thereby protecting the signal traces below and the overall structure.

Referring to FIG. 3, in an embodiment of the present disclosure, in the second region Q2, an end where the second insulating layer 82 terminates overlaps with the isolation protection portion 70 in the direction perpendicular to the plane of the substrate.

In the display panel, some inorganic insulating layers (such as the second insulating layer 82) may contain trace amounts of residual ammonia gas during the manufacturing process. Under the action of high temperatures, this residual ammonia gas will volatilize from the inorganic insulating layer. When moisture intrudes, the volatilized ammonia gas dissolves in water to form a weak base, which significantly promotes the ionization of water and generates more hydroxide ions. In the related art, iodine ions in the polarizer react with hydroxide ions to generate stronger iodate ions, which are strong oxidizing agents. When the electric field of the first signal trace L1 attracts iodine ions and hydroxide ions to the vicinity of the first signal trace L1 to react and form iodate ions with strong oxidizing effects, the iodate ions will cause serious oxidative corrosion to the first signal trace L1 made of metal material, ultimately leading to abnormal dark spots in the display panel.

In the embodiments, when the isolation protection portion 70 is introduced into the second region Q2, a first isolation protection portion 71 is located on the side of the first insulating layer 11 away from the substrate, and the first isolation protection portion 71 overlaps with the end where the second insulating layer 82 terminates in the direction perpendicular to the substrate. The first isolation protection portion 71 may be located between the second insulating layer 82 and the first insulating layer 11 in the direction perpendicular to the substrate. For example, referring to FIG. 3, even if the second insulating layer 82 has residual ammonia gas and the ammonia gas reacts with water to generate hydroxide ions, since the polarity of the electrical signal received by the isolation protection portion 70 is opposite to the polarity of the electrical signal received by the first signal trace L1, when the signal received by the first signal trace L1 is a positively charged signal and the electrical signal received by the isolation protection portion 70 is a negatively charged signal, the isolation protection portion 70 can repel the aforementioned negatively charged hydroxide ions and simultaneously repel the negatively charged iodine ions in the polarizer 90. Even if the iodine ions and hydroxide ions react to generate stronger iodate ions, the position where the reaction occurs will be isolated by the isolation protection portion 70 at a position close to the polarizer 90, making it unable to reach the position of the first signal trace L1. This effectively avoids the problem of oxidative corrosion of the first signal trace L1 by iodate ions, which is beneficial for improving the reliability of the display panel.

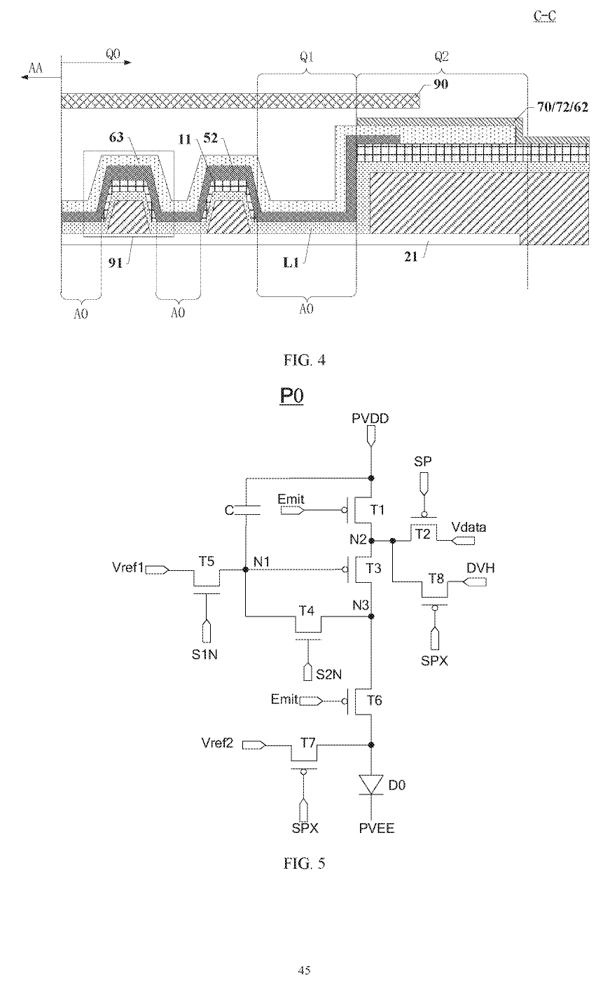

In some embodiments of the present disclosure, the isolation protection portion 70 may also be located on the side of the second insulating layer 82 away from the first insulating layer 11. For example, referring to FIG. 4, the isolation protection portion 70 can isolate the polarizer 90 from the second insulating layer 82. Even if the second insulating layer 82 has residual ammonia gas and the ammonia gas reacts with water to generate hydroxide ions, since the isolation protection portion 70 is located between the polarizer 90 and the second insulating layer 82 and overlaps with the end where the second insulating layer 82 terminates, the hydroxide ions will be unable to meet the iodine ions in the polarizer 90. The two will be unable to react to generate iodate ions, thereby avoiding the problem of oxidative corrosion of the first signal trace L1 by iodate ions, which is beneficial for improving the reliability of the display panel. FIG. 4 shows another cross-sectional view along a line CC of the display panel in FIG. 1.

Referring to FIG. 1, FIG. 3, and FIG. 4, in an embodiment of the present disclosure, the non-display region NA further includes at least one barrier wall 91, which is disposed surrounding the display region AA. In the step region Q0, the first region Q1 is located between the barrier wall 91 and the second region Q2. The barrier wall 91 is a structure having a certain height or thickness and serves as a barrier on the periphery of the display region AA. It forms a ring-shaped sealing structure intended to block moisture and environmental pollutants outside the display region AA as much as possible, acting as a physical barrier. In the display panel, the barrier wall 91 can be composed of various materials, such as polymers and inorganic materials, and is designed to improve sealing performance and hinder the penetration of external pollutants (such as moisture and oxygen) into the interior of the display region.

In the step region Q0, the first region Q1 is located between the barrier wall 91 and the second region Q2, meaning the barrier wall 91 is closer to the display region AA than the first region Q1 and the second region Q2. As a physical barrier surrounding the display region AA, the primary role of the barrier wall 91 is to directly block the penetration of moisture and oxygen into the display region AA. When pursuing extreme narrow bezels, the physical path for moisture intrusion into the display region AA is naturally very short. Placing the barrier wall 91 at the position closest to the display region AA maximizes the use of its physical blocking capability, effectively compensating for the reliability decline caused by the shortened path. The introduction of the barrier wall 91 directly reduces the total amount of moisture reaching the interior of the display region AA. In practical applications, one barrier wall 91 may be disposed on the periphery of the display region AA, or two or more barrier walls 91 may be disposed to enhance the blocking effect on moisture and oxygen. The embodiment only take the arrangement of two barrier walls 91 on the periphery of the display region AA as an example for illustration, but the present disclosure is not limited thereto.

In the embodiments, the second region Q2 is located on the side of the first region Q1 away from the barrier wall 91. In the second region Q2, through the action of multiple insulating layers and the isolation protection portion 70, additional physical and electrical protection is provided, which is beneficial for intercepting and weakening the invasion of moisture and corrosive ions. In the first region Q1 adjacent to the second region Q2, the second insulating layer 82 (inorganic material layer) is in direct contact with the first signal trace L1, providing strong insulation protection for the first signal trace L1 and ensuring that it is protected from moisture. Disposing the barrier wall 91 on the side of the first region Q1 close to the display region AA further extends the physical path of moisture intrusion. Therefore, the effective cooperation of the second region Q2, the first region Q1, and the barrier wall 91 can significantly improve the reliability of the display panel under high-temperature and high-humidity environments, effectively solving the dark spot problem caused by moisture intrusion and ionic corrosion.

In an embodiment of the present disclosure, the display panel further includes a pixel driving circuit P0 located in the display region AA. FIG. 5 is a schematic circuit diagram of a pixel driving circuit P0 according to an embodiment of the present disclosure. Referring to FIG. 1, FIG. 3, and FIG. 5, the first signal trace L1 is configured to transmit a first voltage signal to a first power supply terminal PVDD of the pixel driving circuit P0, and the first voltage signal is a positive voltage signal. For example, the first signal trace L1 is a positive power signal line configured to provide a positive power supply for the pixel driving circuit P0.

Taking FIG. 5 as an example, the pixel driving circuit includes a first transistor T1, a second transistor T2, a third transistor T3, a fourth transistor T4, a fifth transistor T5, a sixth transistor T6, a seventh transistor T7, an eighth transistor T8, and a capacitor C. The third transistor T3 is a driving transistor configured to provide a driving current for the light-emitting element D0. A gate electrode, a first electrode, and a second electrode of the

driving transistor are connected to a first node N1, a third node N3, and a second node N2, respectively. A first electrode and a second electrode of the fifth transistor T5 are connected to a gate reset signal terminal Vref1 and the first node N1, respectively, and a gate electrode is connected to a first control signal terminal S1N for receiving a reset control signal. The fifth transistor T5 is configured to provide a gate reset signal Vref1 to the first node N1. A first electrode and a second electrode of the second transistor T2 are connected to a data voltage signal terminal Vdata and the second node N2, respectively, and a gate electrode receives a control signal SP. The second transistor T2 is configured to transmit the data voltage signal Vdata to the second node N2. It should be noted that in some embodiments of the present disclosure, signal terminals and the signals transmitted by the signal terminals are denoted by the same reference signs. A first electrode and a second electrode of the fourth transistor T4 are connected to the third node N3 and the first node N1, respectively, and a gate electrode is connected to a second control signal terminal S2N for receiving a control signal. The fourth transistor T4 is configured to perform threshold compensation for the third transistor T3. A first electrode and a second electrode of the seventh transistor T7 are connected to an anode reset signal terminal Vref2 and the first electrode of the light-emitting element D0, respectively, and a gate electrode is connected to a control signal terminal SPX. The seventh transistor T7 is configured to reset the first electrode (e.g., anode) of the light-emitting element D0. A first electrode and a second electrode of the eighth transistor T8 are connected to a bias adjustment signal terminal DVH and the second node N2, respectively, and a gate electrode is connected to the control signal terminal SPX. A first electrode and a second electrode of the first transistor T1 are connected to the first power supply terminal PVDD and the second node N2, respectively, and a gate electrode is connected to a light-emitting control signal terminal Emit. A first electrode and a second electrode of the sixth transistor T6 are connected to the third node N3 and the first electrode of the light-emitting element D0, respectively, and a gate electrode is connected to the light-emitting control signal terminal Emit for transmitting the driving current to the light-emitting element D0. A second electrode of the light-emitting element D0 is connected to a second power supply terminal PVEE. It should be

noted that the embodiments of the present disclosure only take the case where the gate electrodes of the seventh transistor T7 and the eighth transistor T8 are both connected to the control signal terminal SPX as an example for illustration, but the present disclosure is not limited thereto.

It should be noted that the pixel driving circuit P0 shown in FIG. 5 is only an example and does not limit the actual circuit structure of the pixel driving circuit in the display panel. In some embodiments of the present disclosure, pixel driving circuits of other structures may also be used according to actual situations. The first signal trace L1 mentioned in this embodiment is configured to provide a positive voltage signal to the first power supply terminal PVDD in the pixel driving circuit P0.

Since the first signal trace L1 transmits a positive voltage signal, it naturally attracts negatively charged iodine ions in the polarizer 90. In the related art, this electrostatic attraction causes these corrosive anions to gather near the first signal trace L1, greatly increasing the probability of corrosion. In some embodiments of the present disclosure, the isolation protection portion 70 receiving a negative voltage signal is introduced in the second region Q2 to create a negative electric field that opposes the attraction of the first signal trace L1. This negative electric field strongly repels negatively charged corrosive ions, preventing them from gathering on the first signal trace L1, thereby fundamentally inhibiting the corrosion of the first signal trace L1.

Referring to FIG. 1, in an embodiment of the present disclosure, the signal trace further includes a second signal trace L2. In the second region Q2, the signal transmitted by the second signal trace L2 is different from the signal transmitted by the first signal trace L1, and the isolation protection portion 70 is electrically connected to the second signal trace L2.

The signal transmitted by the second signal trace L2 is different from the signal transmitted by the first signal trace L1. The second signal trace L2 may transmit a negative voltage signal. When the second signal trace L2 transmits a negative voltage signal, the second signal trace L2 transmits a negative voltage to the isolation protection portion 70. The isolation protection portion 70 will exert a strong repulsion force on the negatively charged corrosive ions, thereby providing a stronger electrostatic shielding effect and maximizing the inhibition of negative ion accumulation.

In some embodiments of the present disclosure, when the isolation protection portion 70 is electrically connected to the existing second signal trace L2 in the display panel, there is no need to introduce an additional signal line separately for the isolation protection portion 70, which is beneficial for simplifying the trace layout and driving design.

In some embodiments, the first signal trace L1 and the second signal trace L2 are located in the same layer. For example, both are located in the third metal layer. In this way, the first signal trace L1 and the second signal trace L2 can be formed in the same manufacturing process, which is beneficial for simplifying the manufacturing process of the display panel and improving production efficiency. Disposing the first signal trace L1 and the second signal trace L2 in the same layer is also beneficial for simplifying the film layer structure of the display panel. In some other embodiments of the present disclosure, the first signal trace L1 and the second signal trace L2 may also be disposed in different film layers. For example, one is located in the third metal layer m3 and the other is located in the second metal layer m2, which is beneficial for reducing the risk of potential electrical crosstalk between the first signal trace L1 and the second signal trace L2 that transmit different signals. In some embodiments of the present disclosure, the first signal trace L1 and the second signal trace L2 may also be disposed in two metal layers using a dual-layer wiring method, such as in the second metal layer and the third metal layer, to reduce the voltage drop of the first signal trace L1 and the second signal trace L2.

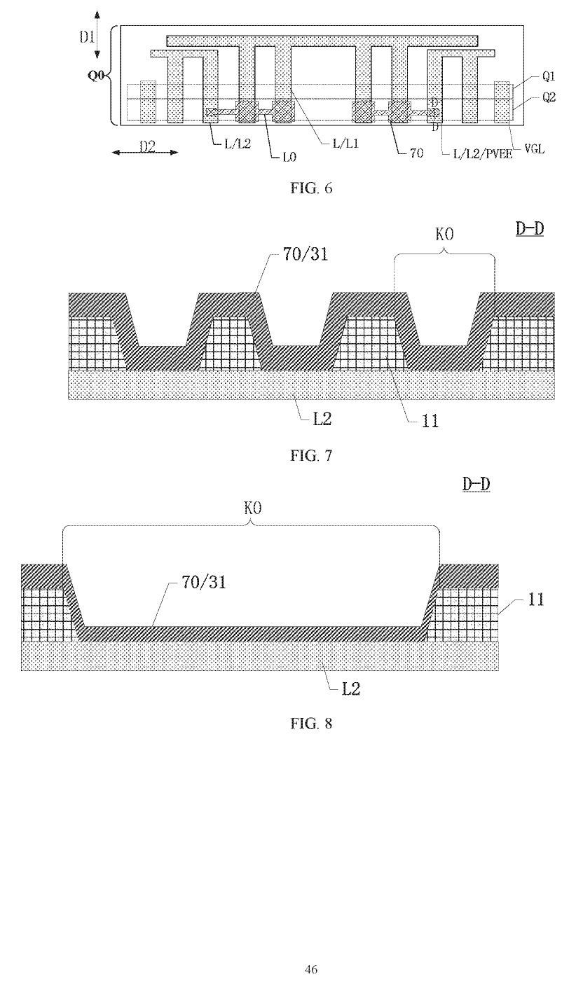

FIG. 6 is a diagram showing a relative positional relationship among the isolation protection portion 70, the first signal trace L1, and the second signal trace L2 in the step region Q0. FIG. 7 is a cross-sectional view along a line DD of the display panel in FIG. 6. Referring to FIG. 6 and FIG. 7, in an embodiment of the present disclosure, in the second region Q2, the isolation protection portion 70 is electrically connected to the second signal trace L2 through a connection hole K0, and the connection hole K0 penetrates at least the first insulating layer 11. In the second region Q2, the first insulating layer 11 is located on a side of the second signal trace L2 away from the substrate. When the electrical connection between the isolation protection portion 70 and the second signal trace L2 is realized through the connection hole K0, and the connection hole K0 penetrates the first insulating layer 11, precise electrical interconnection between the isolation protection portion 70 and the second signal trace L2 located in different layers can be achieved. The connection hole K0 ensures that the second signal trace L2 can stably transmit voltage signals to the isolation protection portion 70, enabling the isolation protection portion 70 to effectively generate an electric field that repels corrosive ions.

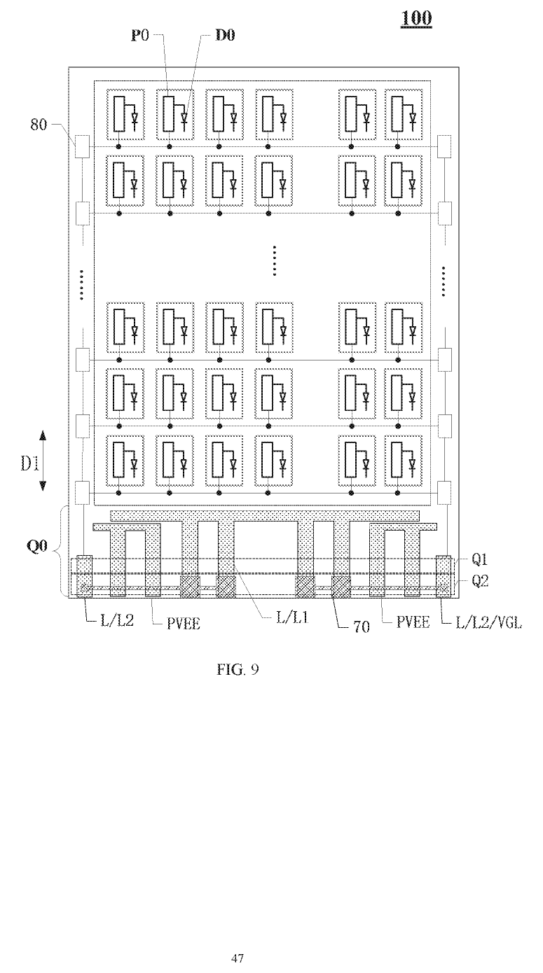

It should be noted that FIG. 7 shows a solution where the isolation protection portion 70 is electrically connected to the second signal trace L2 through a plurality of via holes K0, but the present disclosure is not limited thereto. In some embodiments of the present disclosure, the isolation protection portion 70 may also be electrically connected to the second signal trace L2 through a single via hole K0. For example, referring to FIG. 8, the size of the via hole K0 may be set larger to improve the connection reliability between the isolation protection portion 70 and the second signal trace L2. FIG. 8 shows another cross-sectional view along a line DD of the display panel in FIG. 6.

It should also be noted that when the isolation protection portion 70 is electrically connected to the second signal trace L2, the area of the isolation protection portion 70 overlapping with the second signal trace L2 may be smaller than the area of the isolation protection portion 70 overlapping with the first signal trace L1, as long as a reliable electrical connection between the isolation protection portion 70 and the second signal trace L2 can be realized. The isolation protection portion 70 overlapping with the first signal trace L1 can cover the ends of the first signal trace L1 to increase the range of the negative electric field generated by the isolation protection portion 70, maximizing the isolation of the influence of corrosive ions on the first signal trace L1.

Referring to FIG. 6, in an embodiment of the present disclosure, the second region Q2 includes at least two first signal traces L1 disposed at intervals. Different first signal traces L1 correspond to different isolation protection portions 70, respectively. At least two different isolation protection portions 70 are electrically connected to each other through a connection portion L0, and the isolation protection portions 70 electrically connected to each other are electrically connected to the same second signal trace L2.

In the present disclosure, at least two first signal traces L1 are disposed in the second region Q2, and power signals are transmitted to the pixel driving circuits P0 in the display panel through different first signal traces L1, which is beneficial for improving the transmission efficiency of power signals. In some embodiments, a corresponding isolation protection portion 70 is provided for each first signal trace L1 in the second region Q2, so that each first signal trace L1 in the second region Q2 can obtain direct and targeted electric field shielding protection. This greatly enhances the localization and effectiveness of the protection, ensuring that each first signal trace L1 can inhibit the accumulation of corrosive ions.

In the embodiments, the different isolation protection portions 70 are electrically connected to each other through the connection portion L0, thereby ensuring that the interconnected isolation protection portions 70 maintain the same potential. This helps achieve a uniform distribution of the electric field and prevents electric field weak points in local regions, which is beneficial for providing a more stable ion repulsion effect. Furthermore, the electrically connected isolation protection portions 70 are connected to the same second signal trace L2, eliminating the need for individual wiring for each isolation protection portion 70. This greatly simplifies the wiring structure in the bezel region and helps ensure that all related isolation protection portions 70 receive consistent electrical signals from a stable source, thereby maintaining their ion-repelling function. Under narrow bezel conditions, reusing a single second signal trace L2 to supply power to multiple isolation protection portions 70 is also beneficial for saving valuable space.

Referring to FIG. 6, in an embodiment of the present disclosure, the width of the connection portion L0 in the first direction D1 is smaller than the width of the isolation protection portion 70 in the first direction D1. In OLED display panels with extreme narrow bezels, every inch of space in the non-display region NA is precious. The primary function of the connection portion L0 is to achieve electrical connection. It does not need to cover the first signal trace L1 like the isolation protection portion 70, nor generate a broad electric field to repel ions l. By reducing the width of the connection portion, valuable space can be saved in the horizontal direction. This allows the limited bezel region to accommodate more traces, or larger isolation protection portions, or leave more space for other structures or process margins, thereby better achieving a narrow bezel design.

In addition, considering that in the second region Q2, the connection portion may overlap with other signal lines transmitting different signals, reducing the width of the connection portion helps avoid unnecessary coupling interference between the connection portion and other signal traces, thereby improving the signal stability of the display panel.

In some embodiments of the present disclosure, referring to FIG. 6, the width of the isolation protection portion 70 in the second direction D2 is greater than the width of the first signal trace L1 in the second direction D2. The second direction D2 intersects with the first direction D1, and both are parallel to the light-emitting surface of the display panel. This can increase the coverage area of the isolation protection portion 70 over the first signal trace L1. For example, two edges of the first signal trace L1 extending in the first direction D1 are located between two edges of the isolation protection portion 70 extending in the first direction D1, so that the isolation protection portion 70 generates a broad electric field to repel ions and prevent local electric field weak points, which is beneficial for providing a more stable ion repulsion effect.

Referring to FIG. 1 and FIG. 5, in an embodiment of the present disclosure, the display panel further includes a pixel driving circuit P0 located in the display region AA. The second signal trace L2 is configured to transmit a second voltage signal to a second power supply terminal PVEE of the pixel driving circuit P0, and the second voltage signal is a negative voltage signal.

The second signal trace L2 provides a negative power supply voltage to the pixel driving circuit P0, which constitutes, with the first signal trace L1, the voltage range required to drive pixels. By providing a negative voltage signal to the isolation protection portion 70 through the second signal trace L2 that transmits a negative power signal, the isolation protection portion 70 generates a strong negative electric field with the same polarity as the corrosive anions. This can actively push corrosive anions away from the first signal trace L1, fundamentally solving the problem of the positively charged first signal trace L1 attracting negative ions. In the present disclosure, the positive power signal line and the negative power signal line of the display panel are combined with a reliability protection mechanism, so that the negative power signal line not only provides a negative power supply but also takes on the function of providing active protection for the positive power signal line. This function reuse is more beneficial for achieving a narrow bezel design for the display panel.

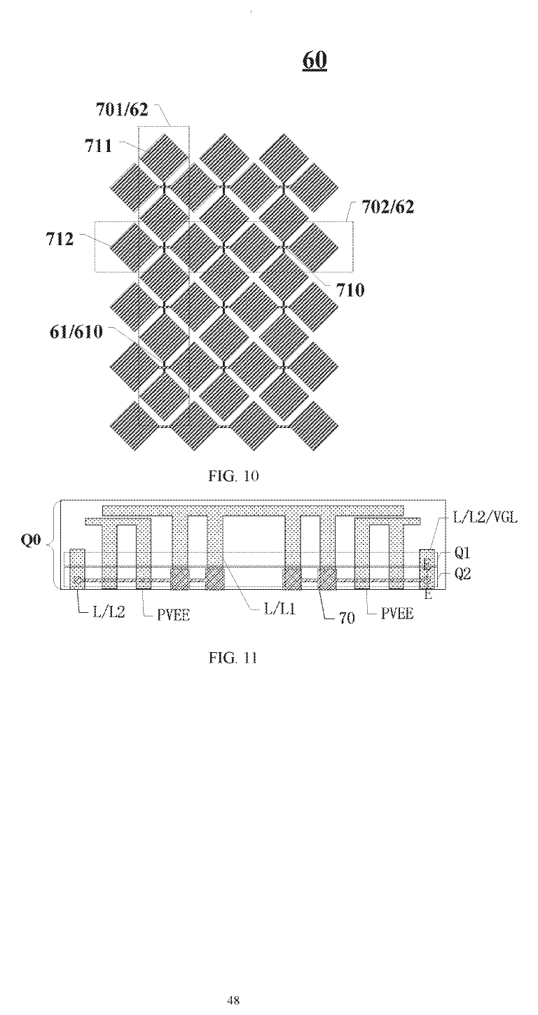

FIG. 9 is a schematic plan view of another display panel according to an embodiment of the present disclosure. Referring to FIG. 9, in an embodiment of the present disclosure, the display panel further includes the pixel driving circuit P0 located in the display region AA. Referring to FIG. 9 and FIG. 10, the display panel further includes a gate driving circuit 80 configured to transmit a gate driving signal to the pixel driving circuit P0. The second signal trace L2 is configured to transmit a second voltage signal to the gate driving circuit 80, and the second voltage signal is a negative voltage signal.

This embodiment describes another feasible embodiment of the second signal trace L2, where the second signal trace L2 is configured to provide a negative voltage signal to the gate driving circuit 80. When this type of second signal trace L2 is electrically connected to the isolation protection portion 70, the isolation protection portion 70 will be able to stably receive and maintain a negative voltage, thereby creating a negative electric field as the same potential as the corrosive ions. This negative electric field will strongly repel negatively charged corrosive ions, preventing them from gathering on the first signal trace L1 and causing corrosion. In this embodiment, an existing second signal line in the display panel used to transmit a negative voltage signal to the gate driving circuit 80 is connected to the isolation protection portion 70, eliminating the need to introduce a separate signal line for the isolation protection portion 70. This allows the second signal trace L2 transmitting the negative voltage signal to not only provide a negative voltage signal to the gate driving circuit 80 but also take on the function of providing active protection for the positive first signal trace L1. This function reuse is beneficial for achieving a narrow bezel design for the display panel.

Referring to FIG. 2 and FIG. 3, in an embodiment of the present disclosure, the display region AA includes an array layer 40 and a light-emitting functional layer 30 electrically connected to the array layer 40. The light-emitting functional layer 30 includes a first electrode 31, a second electrode 33, and a light-emitting layer 32 disposed between the first electrode 31 and the second electrode 33. The first electrode 31 is located on a side of the second electrode 33 facing the substrate 00. The first electrode 31 is electrically connected to the array layer 40. The isolation protection portion 70 includes the first isolation protection portion 71, and the first isolation protection portion 71 is located in the same layer as the first electrode 31.

The first electrode 31 can be regarded as an anode of the light-emitting element D0, and the second electrode 33 can be regarded as a cathode of the light-emitting element D0. The first electrode 31 is electrically connected to the pixel driving circuit P0 through the array layer 40 and receives driving signals. In the stacked structure of the display panel, disposing the isolation protection portion 70 and the first electrode 31 in the same layer means they can share the same manufacturing process steps, such as the same round of photolithography, deposition, and etching. This greatly simplifies the manufacturing process, reduces process steps, and effectively lowers production costs and time. Since the first electrode 31 is located directly below the light-emitting layer 32 and connected to the array layer 40, and corrosion primarily occurs near the first signal trace L1, disposing the first isolation protection portion 71 in the same layer as the first electrode 31 means the first isolation protection portion 71 is very close to the first signal trace L1. This physical proximity allows the negative electric field generated by the isolation protection portion 70 to act more effectively around the first signal trace L1, maximizing the repulsion of corrosive anions.

Referring to FIG. 2 and FIG. 4, in an embodiment of the present disclosure, the display panel further includes a touch layer 60 disposed on a side of the first insulating layer 11 away from the substrate. The touch layer 60 includes at least one touch metal layer 61/62. The isolation protection portion 70 includes a second isolation protection portion 72, and the second isolation protection portion 72 is located in a same layer as the at least one touch metal layer 61/62.

Although the main corrosion problem occurs in the first signal trace L1 close to the display region AA, moisture permeates layer by layer. When the second isolation protection portion 72 is located in the same layer as at least one touch metal layer, the second isolation protection portion 72, as a conductive structure located in an outer layer, will provide an additional, more external electric field shield for the touch layer and its underlying structures if it also receives a negative voltage signal (e.g., by connecting to the second signal trace or another suitable negative voltage source). This can play a role in the early stages of moisture penetration, further hindering the inward diffusion of negatively charged corrosive ions.

Furthermore, by disposing the second isolation protection portion 72 in the same layer as at least one touch metal layer, there is no need to introduce a new film layer structure separately for the second isolation protection portion 72. The second isolation protection portion 72 and the touch metal layer can share the same manufacturing process steps, which is beneficial for simplifying the production process of the display panel, reducing manufacturing costs, and improving production efficiency.

Referring to FIG. 2 and FIG. 4, in an embodiment of the present disclosure, the touch layer includes a first touch metal layer 61, a touch insulating layer 63, and a second touch metal layer 62. In the direction perpendicular to the plane of the substrate, the first touch metal layer 61 is located on a side of the touch insulating layer 63 facing the substrate, and the second touch metal layer 62 is located on a side of the touch insulating layer 63 away from the substrate 00. The second isolation protection portion 72 is located in the same layer as the first touch metal layer 61 and/or the second touch metal layer 62.

FIG. 10 is a schematic plan view of a touch electrode according to an embodiment of the present disclosure. Referring to FIG. 2 and FIG. 10, in an embodiment of the present disclosure, the second touch metal layer 62 is located above the touch insulating layer 63, on a side further away from the substrate. When the touch structure is a mutual-capacitance touch structure, the second touch metal layer 62 can be configured, for example, to dispose a mutual-capacitance first touch electrode 701 and second touch electrode 702, and the first touch metal layer 61 can be configured to dispose a bridge structure 610. In some embodiments, the first touch electrode 701 includes a plurality of first touch electrode blocks 711 electrically connected to each other, and the second touch electrode 702 includes a plurality of second touch electrode blocks 712 electrically connected to each other. The first touch electrode blocks 711 are electrically connected to each other through the bridge structure 610, and the second touch electrode blocks 712 are electrically connected to each other through a connection structure 710 located in the same layer. Alternatively, the first touch electrode blocks 711 are electrically connected to each other through a bridge structure, and the second touch electrode blocks 712 are electrically connected to each other through a connection structure located in the same layer.

In the present disclosure, one feasible implementation is that the second isolation protection portion 72 is in the same layer as the first touch metal layer 61. Another feasible implementation is that the second isolation protection portion 72 is in the same layer as the second touch metal layer 62. Yet another feasible implementation is that a portion of the second isolation protection portion 72 is in the same layer as the first touch metal layer 61, and another portion is in the same layer as the second touch metal layer 62. Disposing the second isolation protection portion 72 in the same layer as existing touch metal layers allows the second isolation protection portion 72 and the touch metal layers to share the same manufacturing process steps, greatly simplifying the production process, reducing manufacturing costs, and improving production efficiency. This integration can maximize the use of existing space and materials in the touch layer, avoiding the addition of independent layers and helping to simplify the overall structure of the display panel.

In some embodiments, when the second isolation protection portion 72 reuses at least one of the first touch metal layer 61 and the second touch metal layer 62, the second isolation protection portion 72 is located in a film layer relatively close to the outside of the display panel, and can serve as a further peripheral electric field barrier on the moisture intrusion path, inhibiting the transfer of iodine ions in the polarizer 90 toward the first signal trace L1, avoiding the reaction of iodine ions with underlying hydroxide ions to generate strongly oxidizing iodate ions, thereby avoiding the problem of oxidative corrosion of the first signal trace L1 by iodate ions, which is beneficial for improving the reliability of the display panel.

In addition, in some embodiments of the present disclosure, when the second isolation protection portion 72 is located in the same layer as the touch metal layer, since the second isolation protection portion 72 receives a constant potential signal, the second isolation protection portion 72 can also provide an electric field shielding effect for the touch metal layer that performs the touch function, reducing the coupling interference of external noise on touch signals.

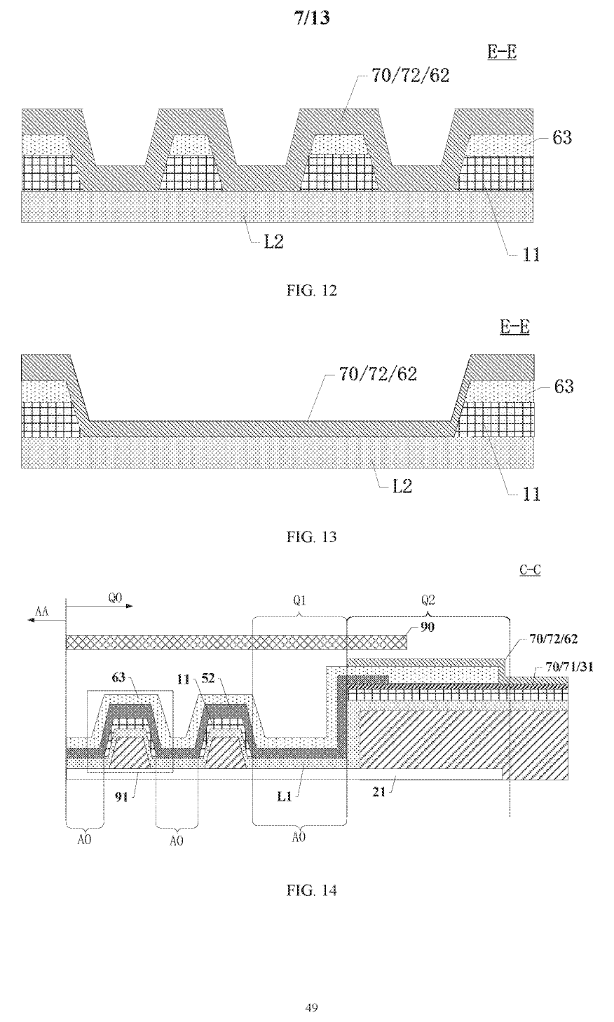

The embodiments shown in FIG. 11 to FIG. 13 illustrate related solutions when the second isolation protection portion 72 is located in the same layer as the second touch metal layer 62. FIG. 11 is a diagram showing another relative positional relationship among the isolation protection portion 70, the first signal trace L1, and the second signal trace L2 in the step region Q0. FIG. 12 is a cross-sectional view along a line EE of the display panel in FIG. 11, and FIG. 13 is another cross-sectional view along a line EE of the display panel in FIG. 11. Referring to FIG. 11 to FIG. 13, when the second isolation protection portion 72 is located in the same layer as the second touch metal layer 62, the second isolation protection portion 72 can be electrically connected to the second signal trace L2 through one or more connection hole penetrating the touch insulating layer 63 and the first insulating layer 11. Realizing the electrical connection between the second isolation protection portion 72 and the second signal trace L2 through connection holes, and the connection holes penetrate the touch insulating layer 63 and the first insulating layer 11 allows for precise electrical interconnection between the second isolation protection portion 72 and the second signal trace L2 located in different layers. The connection holes ensure that the second signal trace L2 can stably transmit voltage signals to the second isolation protection portion 72, enabling the second isolation protection portion 72 to effectively generate an electric field that repels corrosive ions.

Referring to FIG. 2 and FIG. 14, where FIG. 14 is another cross-sectional view along a line CC of the display panel in FIG. 1. In an embodiment of the present disclosure, the display region AA includes the array layer 40 and the light-emitting functional layer 30 electrically connected to the array layer 40. The light-emitting functional layer 30 includes the first electrode 31, the second electrode 33, and the light-emitting layer 32 disposed between the first electrode 31 and the second electrode 33. The first electrode 31 is located on a side of the second electrode 33 facing the substrate 00. The first electrode 31 is electrically connected to the array layer 40. The display panel further includes the touch layer 60 disposed on a side of the light-emitting functional layer 30 away from the substrate 00. The touch layer 60 includes at least one touch metal layer 61/62. In some embodiments, an encapsulation layer 50 is disposed between the touch layer 60 and the light-emitting functional layer 30.

The isolation protection portion 70 includes the first isolation protection portion 71 and the second isolation protection portion 72. The first isolation protection portion 71 is located in the same layer as the first electrode 31, and the second isolation protection portion 72 is located in the same layer as the at least one touch metal layer 61/62. The second isolation protection portion 72 is electrically connected to the first isolation protection portion 71.

This embodiment describes a solution where the display panel includes both the first isolation protection portion 71 and the second isolation protection portion 72. The first isolation protection portion 71 is located in the same layer as the first electrode 31 in the light-emitting functional layer 30, and the second isolation protection portion 72 is located in the same layer as the touch metal layer 61/62. The first isolation protection portion 71 is closer to the first signal trace L1 than the second isolation protection portion 72, providing the most direct and concentrated electric field repulsion for the first signal trace L1. The second isolation protection portion 72 is located in the outer touch metal layer and serves as a peripheral defense barrier on the moisture intrusion path. By electrically connecting the first isolation protection portion 71 and the second isolation protection portion 72, it is ensured that the entire bezel region, from the position close to the first signal trace L1 in the second region Q2 to the surface of the touch layer 60, is covered by a unified and powerful negative electric field, which eliminates potential electric field weak points or dead zones. Even if residual ammonia leads to the generation of hydroxide ions, these negatively charged corrosive ions will encounter the unified negative electric field from the first isolation protection portion 71 and the second isolation protection portion 72 along the entire penetration path and then be strongly repelled. These ions will be concentrated between the first isolation protection portion 71 and the second isolation protection portion 72, unable to approach or corrode the first signal trace L1, and also unable to contact the iodine ions precipitated from the polarizer 90, thereby avoiding the generation of iodate ions with stronger oxidizing properties and effectively improving the reliability of the display panel.

Furthermore, integrating the first isolation protection portion 71 and the second isolation protection portion 72 with existing functional layers maximizes space utilization and simplifies the manufacturing process, which is beneficial for improving production efficiency and simplifying the overall structure of the display panel.

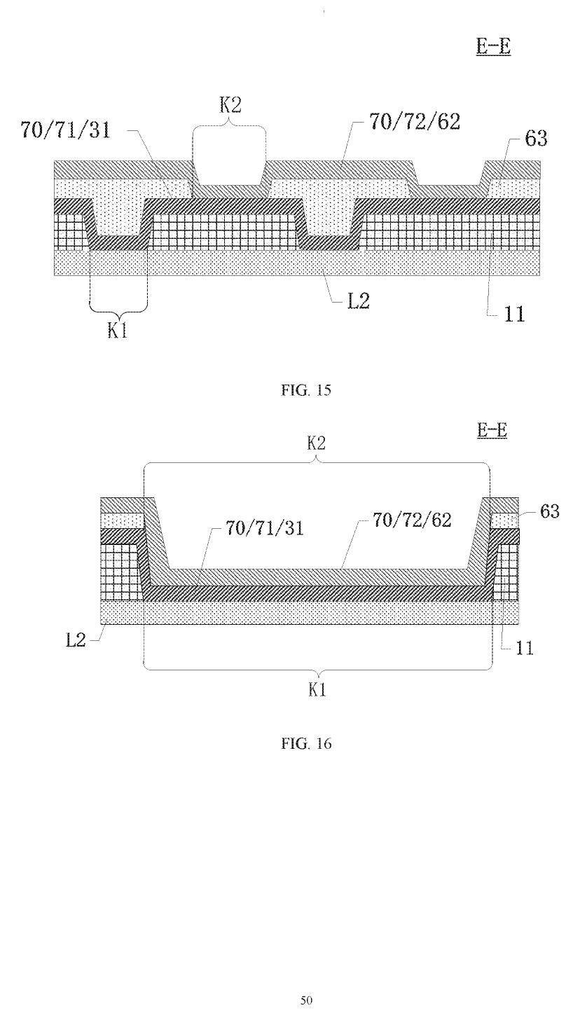

FIG. 15 is another cross-sectional view along a line EE of the display panel in FIG. 11. Referring to FIG. 2, FIG. 11, FIG. 14, and FIG. 15, in an embodiment of the present disclosure, the signal trace L includes a second signal trace L2, and the second signal trace L2 is configured to transmit a second voltage signal. The touch layer includes the first touch metal layer 61, the touch insulating layer 63, and the second touch metal layer 62. In the direction perpendicular to the plane of the substrate, the first touch metal layer 61 is located on a side of the touch insulating layer 63 facing the substrate, and the second touch metal layer 62 is located on a side of the touch insulating layer 63 away from the substrate. The second isolation protection portion 72 is located in the same layer as the second touch metal layer 62. The first isolation protection portion 71 is electrically connected to the second signal trace L2 through a first connection hole K1, and the first connection hole K1 penetrates the first insulating layer 11. The second isolation protection portion 72 is electrically connected to the first isolation protection portion 71 through a second connection hole K2, and the second connection hole K2 penetrates the touch insulating layer 63. It should be noted that the second signal trace L2 mentioned in this embodiment is not limited to a signal trace providing a negative voltage signal to the gate driving circuit, but may also be a signal trace providing a negative power signal to the pixel driving circuit.

This embodiment describes the specific connection relationship when the isolation protection portion 70 includes both the first isolation protection portion 71 and the second isolation protection portion 72. The first isolation protection portion 71 is in the same layer as the first electrode 31 in the light-emitting functional layer and is closer to the first signal trace L1. The first isolation protection portion 71 is electrically connected to the second signal trace L2, enabling the first isolation protection portion 71 to generate the most direct and concentrated negative electric field to strongly repel negatively charged corrosive ions. The first isolation protection portion 71 is directly connected to the second signal trace L2 through the first connection hole K1 (penetrating the first insulating layer 11). This means the negative voltage of the second signal trace L2 can be directly and stably transmitted to the most critical protection layer, ensuring the first isolation protection portion 71 exerts maximum effectiveness. The second isolation protection portion 72 is in the same layer as the second touch metal layer 62 and is located on the relatively outer side of the display panel structure, serving as a more peripheral electric field defense barrier on the moisture intrusion path. The second isolation protection portion 72 is electrically connected to the first isolation protection portion 71 through the second connection hole K2 (penetrating the touch insulating layer 63). This means the negative voltage of the second signal trace L2 is not only transmitted to the first isolation protection portion 71 but also to the second isolation protection portion 72 through the first isolation protection portion 71 and the second connection hole K2. This structure ensures the continuity and uniformity of the entire negative electric field network, extending from the vicinity of the innermost first signal trace L1 to the outer touch layer, forming a multi-layer, progressive active electric field shield. Even if moisture breaks through the external barrier, corrosive ions will be continuously repelled by the negative electric field throughout the penetration path, avoiding corrosion to the first signal trace L1.

In addition, considering that inside the touch layer (e.g., referring to FIG. 10), some electrode blocks on the second touch metal layer 62 need to be electrically connected to the bridge structure 610 in the first touch metal layer 61 through connection holes, and the connection holes penetrate the touch insulating layer 63. When the second isolation protection portion 72 is connected to the first isolation protection portion 71 through the second connection hole K2, this second connection hole K2 can be manufactured using the same process as the connection holes inside the touch layer. There is no need to introduce new equipment or new process windows. Multiple types of connection holes can be completed on the same production line using the same materials and equipment, thereby significantly reducing the overall process steps. Due to the reuse of the process, time delays caused by process switching or new process verification can be avoided, thereby shortening the product production cycle.

Referring to FIG. 2 and FIG. 15, in an embodiment of the present disclosure, the first connection hole K1 does not overlap with the second connection hole K2 in the direction perpendicular to the substrate 00. When the first connection hole K1 and the second connection hole K2 are set in a non-overlapping manner, the second connection hole K2 is located above the first insulating layer 11 and exposes the first electrode 31 above the first insulating layer 11. This can reduce the depth of the second connection hole K2, realizing the electrical connection between the second isolation protection portion 72 and the first isolation protection portion 71 while reducing the manufacturing difficulty of the second connection hole K2.

Moreover, since the first isolation protection portion 71 is connected to the second signal trace L2 through the first connection hole K1, when the second isolation protection portion 72 is connected to the first isolation protection portion 71 through the second connection hole K2, the second isolation protection portion 72 can obtain a signal as the same potential as the first isolation protection portion 71. There is no need to separately provide a connection hole for the second isolation protection portion 72 to connect with the second signal trace L2, thereby avoiding the complex process associated with forming a connection hole between the second isolation protection portion 72 and the second signal trace L2.

FIG. 16 is another cross-sectional view along a line EE of the display panel in FIG. 11. Referring to FIG. 2 and FIG. 16, in an embodiment of the present disclosure, the second connection hole K2 communicates with the first connection hole K1 in the direction perpendicular to the substrate. During actual manufacturing, the first connection hole K1 may first be formed in the first insulating layer 11 to expose the second signal trace L2, and the first electrode 31 (first isolation protection portion 71) is filled into the first connection hole K1 to form a reliable electrical connection with the second signal trace L2. When subsequently manufacturing the touch layer, the first touch metal layer 61 and the touch insulating layer 63 at the position corresponding to the first connection hole K1 can be removed, while the second touch metal layer 62 at the position of the first connection hole K1 is retained as part of the second isolation protection portion 72, which is electrically connected to the first isolation protection portion 71 at the position of the first connection hole K1 and receives the second voltage signal transmitted by the second signal trace L2 through the first isolation protection portion 71. In this way, there is no need to separately provide a connection hole for the second isolation protection portion 72 to connect with the second signal trace L2, avoiding the complex process associated with forming a connection hole between the second isolation protection portion 72 and the second signal trace L2, which is beneficial for simplifying the production process and improving production efficiency.

It should be noted that when electrically connecting the isolation protection portion 70 to the second signal trace L2, the number of connection holes may be set according to the spatial dimension of the second signal trace L2 in the first direction. When the dimension of the second signal trace L2 in the first direction is large, a plurality of connection holes may be provided to achieve reliable electrical connection between the isolation protection portion 70 and the second signal trace L2. When the dimension of the second signal trace L2 in the first direction is small, a smaller number of connection holes may be provided to realize the electrical connection between the second signal trace L2 and the isolation protection portion 70. The present disclosure does not limit the specific number of connection holes.

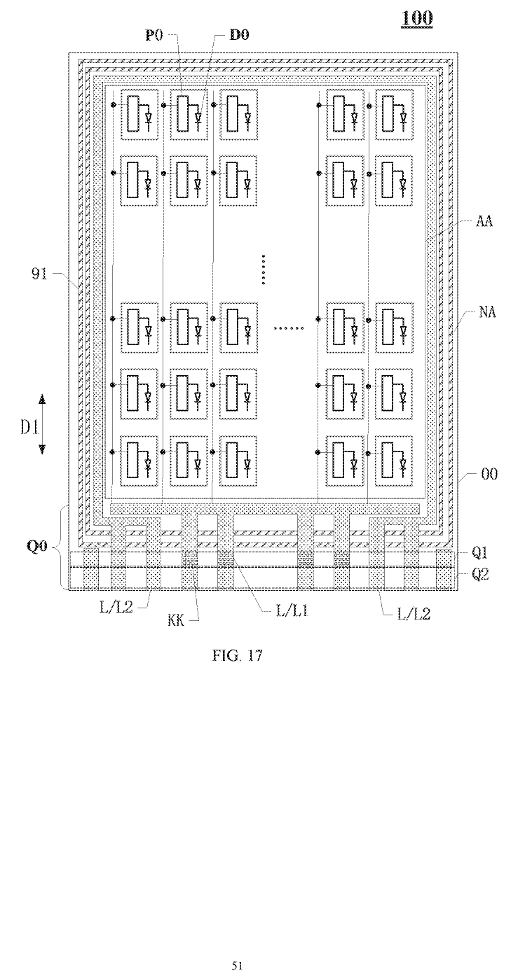

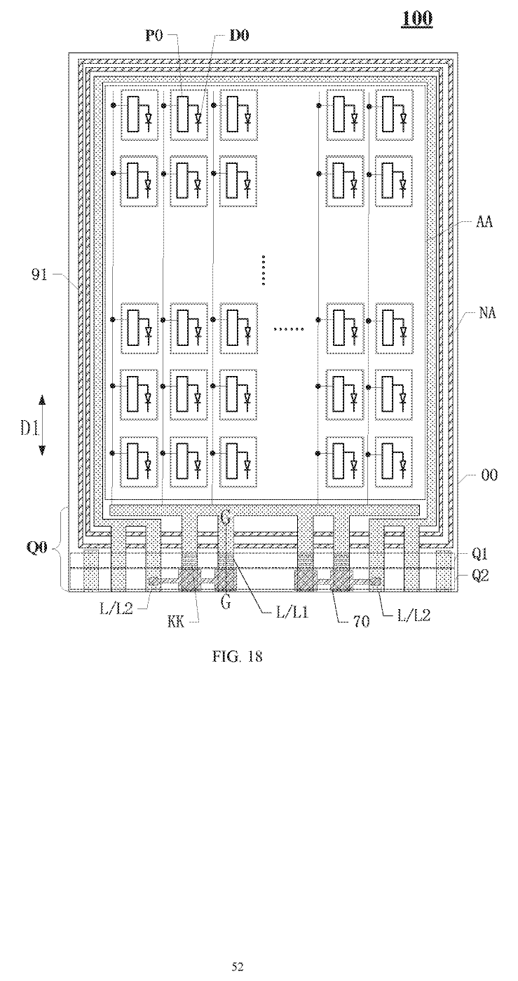

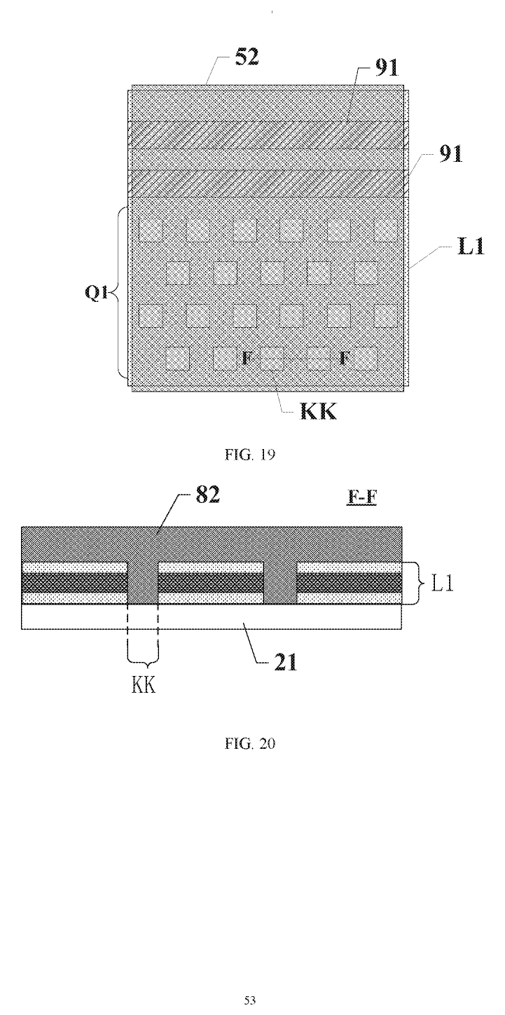

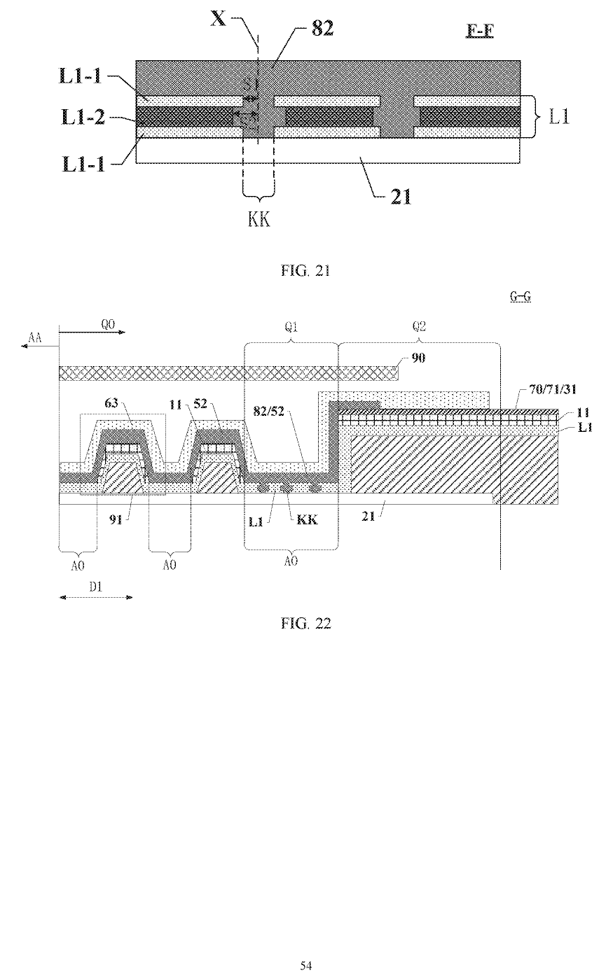

FIG. 17 is a schematic plan view of another display panel according to an embodiment of the present disclosure, FIG. 18 is a schematic plan view of another display panel according to an embodiment of the present disclosure, FIG. 19 is a schematic plan view of the first region Q1 in the display panel according to the embodiments of FIG. 17 and FIG. 18, and FIG. 20 is a cross-sectional view along a line FF of the display panel in FIG. 19. Referring to FIG. 17 to FIG. 20, in an embodiment of the present disclosure, in the first region Q1, the first signal trace L1 includes a plurality of first openings KK, and the second insulating layer 82 at least partially fills the first openings KK. In some embodiments, many small, regular holes or grooves may be etched from the surface of the first signal trace L1 away from the substrate as the first openings KK. The shape is not limited in the present disclosure and may be circular, square, or elongated. When depositing the second insulating layer 82, the material flows into and fills these first openings, forming tiny rivet structures that penetrate deep into the first signal trace L1 to create a mechanical interlock. This interlock significantly increases the bonding strength between the second insulating layer 82 and the first signal trace L1. While the openings are concave, they microscopically increase the effective contact area between the second insulating layer 82 and the first signal trace L1. A larger contact area usually means stronger physical adsorption and chemical bonding forces (if present), thereby enhancing the adhesion of the two materials at the interface. The structure in which the second insulating layer 82 fills the first signal trace L1 through the first openings KK also sets up an additional barrier for the lateral penetration of moisture. If moisture attempts to permeate along the interface between the first signal trace L1 and the second insulating layer 82, it will be “blocked” by the insulating material filled in the openings or forced to change its penetration path, thereby extending the penetration path, reducing the penetration rate, and further enhancing the waterproof protection of the first signal trace L1.

FIG. 21 is another cross-sectional view along a line FF of the display panel in FIG. 19. Referring to FIG. 21, in an embodiment of the present disclosure, in the direction perpendicular to the plane of the substrate, the first signal trace L1 includes two first-type metal layers L1-1 and a second-type metal layer L1-2 located between the two first-type metal layers L1-1. The first opening KK exposes side surfaces of the first-type metal layers L1-1 and the second-type metal layer L1-2. In a direction parallel to the plane of the substrate, in the same first opening KK, a distance S1 between one of the first-type metal layers L1-1 and a centerline X of the first opening KK is smaller than a distance S2 between the second-type metal layer L1-2 and the centerline X of the first opening KK. The centerline X of the first opening KK is perpendicular to the plane of the substrate. In this way, it is equivalent to forming an undercut structure in the first signal trace L1. Under the same conditions, an etching rate of the first-type metal layer L1-1 is greater than an etching rate of the second-type metal layer L1-2, so that a diameter of the second-type metal layer L1-2 in an opening region is larger, while a diameter of the first-type metal layer L1-1 in the opening region is smaller. The second-type metal layer L1-2 protrudes inward at an edge of the opening, forming a concave structure. Thus, when the second insulating layer 82 is filled into the first opening KK, it is filled into the concave structure as well, which increases an effective contact area between the second insulating layer 82 and a sidewall of the first signal trace L1, forming a mechanical interlock structure and enhancing interfacial adhesion. It not only significantly improves delamination resistance under thermal stress and mechanical stress, but more critically, forms a gapless physical barrier to block a penetration path of moisture along the interface to the maximum extent. Since the second insulating layer 82 is mechanically locked inside the first signal trace L1, it is almost impossible for moisture to undergo lateral penetration along the interface between the first signal trace L1 and the second insulating layer 82. Any moisture attempting to penetrate will be blocked by this dense mechanical interlock structure, further improving the waterproof and anti-corrosion capability of the first signal trace L1.

Referring to FIG. 21, in an embodiment of the present disclosure, at least part of the second insulating layer 82 is in contact with both the first-type metal layers L1-1 and the second-type metal layer L1-2. When the first-type metal layer L1-1 and the second-type metal layer L1-2 in the first signal trace L1 form the undercut structure, and the second insulating layer 82 is in contact with both the first-type metal layer L1-1 and the second-type metal layer L1-2, a primary mechanical interlock is formed with the undercut structure, greatly increasing a total contact area. A larger contact area means stronger physical adsorption force and possibly chemical bonding force, thereby comprehensively improving the adhesion strength of the entire interface between the second insulating layer 82 and the first signal trace L1. If the second insulating layer 82 can contact all three metal layers, this strongly indicates that the material of the second insulating layer 82 achieves defect-free and dense filling within the first opening KK. Any void or non-contact region could become a potential path for moisture penetration. This full-contact design ensures the integrity of the filling, thereby physically preventing the possibility of moisture penetration along the interface to the maximum extent. Even if different metal layers exist inside the first signal trace L1, this design also ensures that the waterproof insulating layer can effectively encapsulate the entire structure, avoiding weaknesses caused by the complexity of material interfaces.

Referring to FIG. 20 and FIG. 21, in an embodiment of the present disclosure, in a direction perpendicular to the substrate, the first opening KK penetrates the first signal trace L1. When the first opening KK adopts a through-type design, the first opening KK will expose the insulating layer 21 below the first signal trace L1. When the second insulating layer 82 fills the first opening KK, it can not only contact the sidewall (including the undercut structure) of the first opening KK in the first signal trace L1, but also extend to the insulating layer 21 below the first signal trace L1 to contact the insulating layer 21, thereby forming a deeper and firmer “rivet” or “mechanical lock” effect, which greatly enhances the mechanical interlocking force between the second insulating layer 82 and the first signal trace L1. In this way, the first signal trace L1 is fixed in a three-dimensional manner by the second insulating layer 82 above it, the original insulating layer below it, and the undercut structure inside the first opening KK. This multi-face contact greatly enhances the overall adhesion and sealing around the first signal trace L1. The multi-layer contact and deeper anchoring structure can more effectively disperse and absorb stress generated by differences in thermal expansion coefficients or external mechanical stress, further improving the long-term stability and crack resistance of the structure. If moisture attempts to penetrate the interface of the first signal trace L1, it must now bypass a more complex and firmer insulating layer encapsulation structure. This makes the moisture penetration path longer and more difficult, further improving the waterproof and anti-corrosion capability of the first signal trace L1.

FIG. 22 is a cross-sectional view along a line GG of the display panel in FIG. 18. Referring to FIG. 18 and FIG. 22, the non-display region of the display panel includes a plurality of organic-free regions A0. The organic-free region A0 refers to a region where the first insulating layer 11 is not provided and the second insulating layer 82 and the first signal trace L1 are in direct contact. The plurality of organic-free regions A0 may be respectively located between the barrier wall 91 and the display region AA, between adjacent barrier walls 91, and on a side of the barrier wall 91 away from the display region AA. When the first opening KK is provided on the first signal trace L1, the first opening KK may be preferentially provided in the first region Q1 (i.e., the organic-free region A0 on the side of the barrier wall 91 away from the display region AA). Compared with other organic-free regions A0, the first region Q1 is furthest from the display region, so the outermost defense barrier can be utilized to prevent moisture from intruding toward the display region. In some embodiments of the present disclosure, the first opening KK may also be correspondingly provided in one or more of the other organic-free regions A0 to enhance the adhesion of the second insulating layer 82 and the first signal trace L1 at the interface, further enhancing the waterproof protection function of the display panel.

Referring to FIG. 2 and FIG. 21, in an optional embodiment of the present disclosure, the display region AA includes the array layer 40 and the light-emitting functional layer 30 electrically connected to the array layer 40. The light-emitting functional layer 30 includes the first electrode 31, the second electrode 33, and the light-emitting layer 32 disposed between the first electrode 31 and the second electrode 33. The first electrode 31 is located on a side of the second electrode 33 facing the substrate 00. The first electrode 31 is electrically connected to the array layer 40. The first opening KK and the first electrode 31 are manufactured in the same etching process. In the present disclosure, by integrating the etching of the first opening KK on the first signal trace L1 and the patterning of the first electrode into one etching step, the overall manufacturing process is greatly simplified. This reduces the number of required masks, photolithography steps, and etching cycles. The reduction of steps directly translates into faster manufacturing time and higher capacity. Process integration reduces material waste, energy consumption, and equipment usage, directly lowering the manufacturing cost of the display panel.

Referring to FIG. 18, an embodiment shows a solution in which the isolation protection portion 70 is introduced in the second region Q2, and the first opening KK is introduced in the first signal trace L1 in the first region Q1. In the second region Q2, an opposite electric field is formed between the isolation protection portion 70 and the first signal trace L1. When negatively charged iodine ions are precipitated in the polarizer 90, the negative electric field around the isolation protection portion 70 will exert a powerful electrostatic repulsion force on the negatively charged iodine ions. Through this electrostatic repulsion effect, gathering of iodine ions near the first signal trace L1 with a positive potential can be effectively prevented or substantially reduced, thereby fundamentally eliminating or mitigating the risk of iodine ions causing corrosion to the first signal trace L1. Once iodine ions are effectively repelled, the probability of them reacting with moisture ionization products to generate oxides that corrode power supply lines is greatly reduced. When the first opening KK is introduced in the first region Q1, and the second insulating layer 82 is deposited, its material will flow into and fill these first openings KK. The insulating material filled in the first openings KK forms tiny rivet structures that penetrate deep into the structure of the first signal trace L1, forming a mechanical interlock. This interlocking effect greatly increases the bonding strength between the second insulating layer 82 and the first signal trace L1, providing an additional barrier for the lateral penetration of moisture. Therefore, the corrosion of the first signal trace L1 by corrosive ions is blocked by the isolation protection portion 70, and the interfacial adhesion between the second insulating layer 82 and the first signal trace L1 is increased by the first opening KK to cut off the moisture path. Through multi-layer synergistic defense, the corrosion problem is effectively solved, the waterproof performance of the display panel is effectively improved, and the reliability of the display panel is enhanced.

Referring to FIG. 2 and FIG. 3, in an embodiment of the present disclosure, the display panel includes the array layer 40, the light-emitting functional layer 30, and the encapsulation layer 50. The light-emitting functional layer 30 is located on a side of the array layer 40 away from the substrate. The encapsulation layer 50 is located on a side of the light-emitting functional layer 30 away from the substrate 00 and covers at least the display region. The encapsulation layer 50 includes the organic layer 51 and an inorganic layer 52 that are arranged in a stacked manner. In the step region Q0, the inorganic layer 52 is reused as the second insulating layer 82. In some embodiments, the encapsulation layer includes two inorganic layers 52, and the organic layer 51 is located between the two inorganic layers 52.

In the present disclosure, the encapsulation layer 50 is introduced on the side of the light-emitting functional layer 30 away from the substrate 00. The encapsulation layer 50 covers the entire display region of the display panel and extends at least to the non-display region to protect the light-emitting functional layer, which is extremely sensitive to moisture and oxygen, from environmental erosion. The encapsulation layer 50 adopts a combined structure of the organic layer 51 and the inorganic layer 52. The organic layer 51 can provide planarization and stress buffering, and the inorganic layer 52 provides a primary barrier function, so that the encapsulation layer 50 as a whole has certain flexibility while achieving moisture and oxygen barrier performance. The inorganic layer 52 in the encapsulation layer 50 extends to the step region Q0 and is reused as the second insulating layer 82, which increases the coverage area of the inorganic layer in the encapsulation layer 50 in the display panel and is beneficial for improving overall encapsulation reliability. By reusing the inorganic layer in the encapsulation layer 50 as the second insulating layer 82 in the step region Q0, additional deposition and patterning steps can be reduced. There is no need to deposit another layer of insulating material separately, thereby saving manufacturing time and cost. The inorganic layer 52 of the encapsulation layer 50 itself has excellent moisture and oxygen barrier performance and density, and reusing it as the second insulating layer 82 in the step region Q0 can provide high-quality insulation and waterproof protection for signal traces in the step region Q0.

Referring to FIG. 3, in an embodiment of the present disclosure, the display panel further includes the polarizer 90. The polarizer 90 is located at least in the display region AA and at least part of the step region Q0. In the step region Q0, in a direction perpendicular to the plane of the substrate, the polarizer 90 covers the first region Q1 and overlaps with at least part of the second region Q2.

In some embodiments of the present disclosure, when the polarizer 90 is introduced into the display panel, the polarizer 90 covers the display region AA and simultaneously extends to the first region Q1 and the second region Q2, ensuring that light emitted from the display region AA can all be regulated by the polarizer 90, so as to improve the overall contrast of the display panel. The polarizer 90 usually contains a polyvinyl alcohol (PVA) layer, which is a hygroscopic material. When the environmental humidity is high, the polarizer 90 will absorb moisture. If the polarizer 90 contains iodine or other halogens, these substances will ionize in the presence of moisture to form negatively charged iodine ions. Residual ammonia in the second insulating layer 82 reacts with water to generate hydroxide ions. When the negatively charged iodine ions and hydroxide ions are attracted to the vicinity of the first signal trace L1 by the positively charged first signal trace L1, the two react to generate iodate ions with stronger oxidizing properties, which will cause oxidative corrosion to the first signal trace L1. Therefore, in some embodiments of the present disclosure, the isolation protection portion 70 is introduced in the second region Q2. The first isolation protection portion 71 is located on a side of the first insulating layer 11 away from the substrate, and in a direction perpendicular to the plane of the substrate, the first isolation protection portion 71 overlaps with a terminating end of the second insulating layer 82. In the direction perpendicular to the plane of the substrate, the first isolation protection portion 71 may be located between the second insulating layer 82 and the first insulating layer 11. Even if there is residual ammonia in the second insulating layer 82, and the ammonia reacts with water to generate hydroxide ions, since the polarity of the electrical signal received by the isolation protection portion 70 is opposite to the polarity of the electrical signal received by the first signal trace L1, when the signal received by the first signal trace L1 is a positively charged signal and the electrical signal received by the isolation protection portion 70 is a negatively charged signal, the isolation protection portion 70 can repel the aforementioned negatively charged hydroxide ions and simultaneously repel the negatively charged iodine ions in the polarizer 90. Even if the iodine ions and hydroxide ions react to generate stronger iodate ions, the position where the reaction occurs will be isolated by the isolation protection portion 70 at a position close to the polarizer 90, making it unable to reach the position of the first signal trace L1. This effectively avoids the problem of oxidative corrosion of the first signal trace L1 by iodate ions, which is beneficial for improving the reliability of the display panel. In some embodiments of the present disclosure, the isolation protection portion 70 may also be located on the side of the second insulating layer 82 away from the first insulating layer 11. For example, referring to FIG. 4, in this way, the isolation protection portion 70 can isolate the polarizer 90 from the second insulating layer 82. Even if the second insulating layer 82 has residual ammonia gas and the ammonia gas reacts with water to generate hydroxide ions, since the isolation protection portion 70 is located between the polarizer 90 and the second insulating layer 82 and overlaps with the end where the second insulating layer 82 terminates, the hydroxide ions will be unable to meet the iodine ions in the polarizer 90. The two will be unable to react to generate iodate ions, thereby avoiding the problem of oxidative corrosion of the first signal trace L1 by iodate ions, which is beneficial for improving the reliability of the display panel.

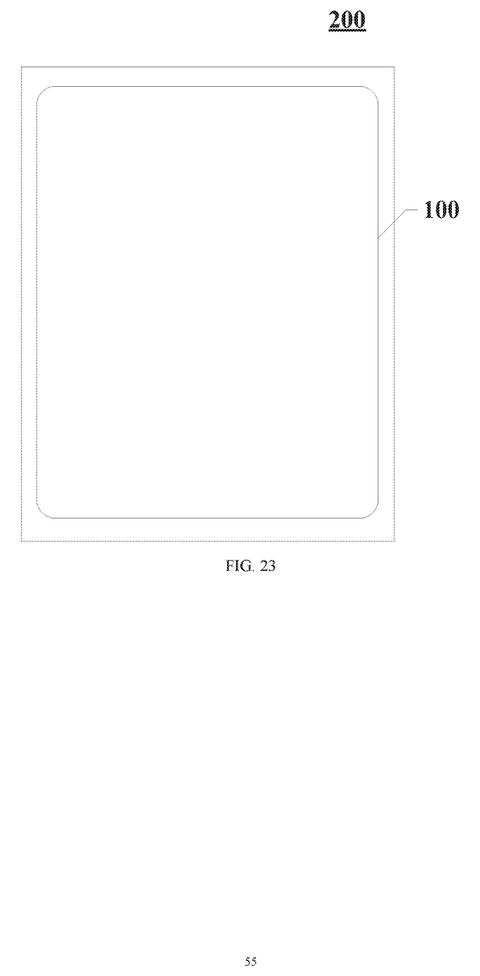

Based on the same inventive concept, the present disclosure further provides a display apparatus 200. FIG. 23 is a schematic structural diagram of a display apparatus 200 according to an embodiment of the present disclosure. Referring to FIG. 23, the display apparatus 200 includes the display panel 100 according to any one of the above embodiments. The display apparatus 200 according to the embodiment of the present disclosure may be any electronic device having a display function, such as a touch display screen, a mobile phone, a tablet computer, a notebook computer, an e-book, or a television. The display apparatus 200 according to the embodiment of the present disclosure has the beneficial effects of the display panel according to the embodiments of the present disclosure. For details, reference may be made to the specific descriptions of the display panel in the above embodiments, which will not be repeated in this embodiment.

It can be understood that FIG. 23 only takes a rectangular structure as an example to illustrate one shape of the display apparatus 200. In some embodiments of the present disclosure, the display apparatus 200 may also be embodied as a circle, an ellipse, or other feasible shape, which is not specifically limited by the present disclosure.

It should be noted that, in this context, relational terms such as “first” and “second” are only used to distinguish one entity or operation from another entity or operation, and do not necessarily require or imply any such actual relationship or order between these entities or operations. Moreover, the terms “include”, “contain”, or any other variant thereof are intended to cover non-exclusive inclusion, such that a process, method, article, or device including a series of elements includes not only those elements, but also other elements not explicitly listed, or further includes elements inherent to such process, method, article, or device. Without more constraints, an element defined by the statement “includes a/an...” does not exclude the existence of other identical elements in the process, method, article, or equipment including the element.

The above are only specific embodiments of the present disclosure to enable those skilled in the art to understand or implement the present disclosure. Various modifications to these embodiments can be derived by those skilled in the art, and the general principles defined herein may be implemented in other embodiments without departing from the spirit or scope of the present disclosure. Therefore, the present disclosure will not be limited to these embodiments described herein, but is to conform to the widest scope consistent with the principles and novel features disclosed herein.

What is claimed is:

1. A display panel, having a display region and a non-display region at least partially surrounding the display region, wherein the non-display region comprises a step region located on a side of the display region in a first direction, the step region comprises a first region and a second region that are arranged in the first direction, and the first region is located between the second region and the display region,
wherein the display panel comprises:
a substrate and a signal trace located on a side of the substrate, wherein the signal trace comprises a first signal trace extending at least from the first region to the second region;
a first insulating layer located on a side of the first signal trace away from the substrate;
a second insulating layer located on a side of the first insulating layer away from the substrate, wherein in the first region, the second insulating layer directly contacts the first signal trace, and in the second region, the first insulating layer is located between the second insulating layer and the first signal trace; and
an isolation protection portion located at least in the second region, wherein in a direction perpendicular to a plane of the substrate, the isolation protection portion overlaps with the first signal trace, and the isolation protection portion is located on the side of the first insulating layer away from the substrate; and the first signal trace is configured to receive a first voltage signal, the isolation protection portion is configured to receive a second voltage signal, and the first voltage signal and the second voltage signal have opposite voltage types.

2. The display panel according to claim 1, wherein in the second region, an end where the second insulating layer terminates overlaps with the isolation protection portion in the direction perpendicular to the plane of the substrate.

3. The display panel according to claim 1, wherein the non-display region further comprises at least one barrier wall surrounding the display region, and in the step region, the first region is located between the at least one barrier wall and the second region.

4. The display panel according to claim 1, further comprising:
a pixel driving circuit located in the display region, wherein the first signal trace is configured to transmit the first voltage signal to a first power supply terminal of the pixel driving circuit, and the first voltage signal is a positive voltage signal.

5. The display panel according to claim 1, wherein the signal trace further comprises a second signal trace, in the second region, a second signal transmitted by the second signal trace is different from a first signal transmitted by the first signal trace, and the isolation protection portion is electrically connected to the second signal trace.

6. The display panel according to claim 5, wherein in the second region, the isolation protection portion is electrically connected to the second signal trace through a connection hole, and the connection hole penetrates at least the first insulating layer.

7. The display panel according to claim 5, wherein the second region comprises at least two first signal traces disposed at intervals, different first signal traces correspond to different isolation protection portions, respectively, and at least two different isolation protection portions are electrically connected to each other through a connection portion and electrically connected to a same second signal trace.

8. The display panel according to claim 7, wherein a width of the connection portion in the first direction is smaller than a width of the isolation protection portion in the first direction.

9. The display panel according to claim 5, further comprising:
a pixel driving circuit located in the display region, wherein the second signal trace is configured to transmit the second voltage signal to a second power supply terminal of the pixel driving circuit, and the second voltage signal is a negative voltage signal.

10. The display panel according to claim 5, further comprising:
a pixel driving circuit located in the display region; and
a gate driving circuit configured to transmit a gate driving signal to the pixel driving circuit, wherein the second signal trace is configured to transmit the second voltage signal to the gate driving circuit, and the second voltage signal is a negative voltage signal.

11. The display panel according to claim 1, wherein the display region comprises an array layer and a light-emitting functional layer electrically connected to the array layer, the light-emitting functional layer comprises a first electrode, a second electrode, and a light-emitting layer disposed between the first electrode and the second electrode, and the first electrode is located on a side of the second electrode facing the substrate and electrically connected to the array layer; and
the isolation protection portion comprises a first isolation protection portion, and the first isolation protection portion is located in a same layer as the first electrode.

12. The display panel according to claim 1, further comprising:
a touch layer disposed on the side of the first insulating layer away from the substrate, wherein the touch layer comprises at least one touch metal layer; and
the isolation protection portion comprises a second isolation protection portion, and the second isolation protection portion is located in a same layer as the at least one touch metal layer.

13. The display panel according to claim 12, wherein the touch layer comprises a first touch metal layer, a touch insulating layer, and a second touch metal layer, in the direction perpendicular to the plane of the substrate, the first touch metal layer is located on a side of the touch insulating layer facing the substrate, and the second touch metal layer is located on a side of the touch insulating layer away from the substrate; and the second isolation protection portion is located in a same layer as the first touch metal layer and/or the second touch metal layer.

14. The display panel according to claim 1, wherein the display region comprises an array layer and a light-emitting functional layer electrically connected to the array layer, the light-emitting functional layer comprises a first electrode, a second electrode, and a light-emitting layer disposed between the first electrode and the second electrode, and the first electrode is located on a side of the second electrode facing the substrate and electrically connected to the array layer;
the display panel further comprises a touch layer disposed on a side of the light-emitting functional layer away from the substrate, the touch layer comprises at least one touch metal layer; and
the isolation protection portion comprises a first isolation protection portion and a second isolation protection portion, the first isolation protection portion is located in a same layer as the first electrode, the second isolation protection portion is located in a same layer as the at least one touch metal layer, and the second isolation protection portion is electrically connected to the first isolation protection portion.

15. The display panel according to claim 14, wherein the signal trace comprises a second signal trace, and the second signal trace is configured to transmit the second voltage signal;
the touch layer comprises a first touch metal layer, a touch insulating layer, and a second touch metal layer, in the direction perpendicular to the plane of the substrate, the first touch metal layer is located on a side of the touch insulating layer facing the substrate, the second touch metal layer is located on a side of the touch insulating layer away from the substrate, and the second isolation protection portion is located in a same layer as the second touch metal layer; and
the first isolation protection portion is electrically connected to the second signal trace through a first connection hole, and the first connection hole penetrates the first insulating layer; and the second isolation protection portion is electrically connected to the first isolation protection portion through a second connection hole, and the second connection hole penetrates the touch insulating layer.

16. The display panel according to claim 15, wherein the first connection hole and the second connection hole do not overlap in the direction perpendicular to the plane of the substrate.

17. The display panel according to claim 15, wherein the second connection hole communicates with the first connection hole in the direction perpendicular to the plane of the substrate.

18. The display panel according to claim 1, wherein in the first region, the first signal trace comprises a plurality of first openings, and the second insulating layer at least partially fills the plurality of first openings.

19. The display panel according to claim 18, wherein in the direction perpendicular to the plane of the substrate, the first signal trace comprises two first-type metal layers and a second-type metal layer located between the two first-type metal layers, and the plurality of first openings expose side surfaces of the two first-type metal layers and the second-type metal layer; and
in a direction parallel to the plane of the substrate, in a same first opening, a distance between one of the two first-type metal layers and a centerline of the first opening is smaller than a distance between the second-type metal layer and the centerline of the first opening, and the centerline of the first opening is perpendicular to the plane of the substrate.

20. A display apparatus, comprising a display panel, having a display region and a non-display region at least partially surrounding the display region, wherein the non-display region comprises a step region located on a side of the display region in a first direction, the step region comprises a first region and a second region that are arranged in the first direction, and the first region is located between the second region and the display region,
wherein the display panel comprises:
a substrate and a signal trace located on a side of the substrate, wherein the signal trace comprises a first signal trace extending at least from the first region to the second region;
a first insulating layer located on a side of the first signal trace away from the substrate;
a second insulating layer located on a side of the first insulating layer away from the substrate, wherein in the first region, the second insulating layer directly contacts the first signal trace, and in the second region, the first insulating layer is located between the second insulating layer and the first signal trace; and
an isolation protection portion located at least in the second region, wherein in a direction perpendicular to a plane of the substrate, the isolation protection portion overlaps with the first signal trace, and the isolation protection portion is located on the side of the first insulating layer away from the substrate; and the first signal trace is configured to receive a first voltage signal, the isolation protection portion is configured to receive a second voltage signal, and the first voltage signal and the second voltage signal have opposite voltage types.
